(19) United States
(12) Patent Application Publication
(10) Pub. No.: US 2007/0281457 A1
(43) Pub. Date: Dec. 6, 2007

(54) Copper layer and a method for manufacturing said copper layer

(75) Inventors: Jinn P. Chu, Keelung (TW); Chon-Hsin Lin, Taipei Hsien (TW)

Correspondence Address: RABIN & Berdo, PC, 1101 14TH STREET, NW, SUITE 500, WASHINGTON, DC, 20005, US

(73) Assignee: Jinn P. CHU, Keelung (TW)

(21) Appl. No.: 11/604,756

(22) Filed: Nov. 28, 2006

(30) Foreign Application Priority Data
May 30, 2006 (TW) 095119091

(51) Int. Cl. H01L 21/44

(52) U.S. Cl. 438/597

(57) ABSTRACT

A copper layer on a substrate has a copper seed layer and an interface. The copper seed layer contains insoluble substances that are insoluble with copper. The interface is formed between the copper seed layer and the substrate. The copper layer replaces a conventional barrier and has significantly improved thermal stability to obtain some properties such as a fine microstructure, high thermal stability and an excellent low electrical resistivity. The copper seed layer is formed by a sputtering process in a vacuum and clean atmosphere with an operational gas of argon or a mixture of argon and a trace-amount of nitrogen. The interface is formed when the copper layer on the substrate are annealed. The insoluble substances in the copper seed layer are in a range of 0.5 to 3.5 atom % and are high-temperature metals and high-temperature metal nitrides with the nitrides being than 2.0 atom %.

### BACKGROUND OF THE INVENTION

1. Field of Invention

The present invention relates to a copper layer and a method for manufacturing said copper layer, and more particularly to a copper layer that has a copper seed layer with insoluble substances to replace a non-reactive barrier on a substrate and is manufactured by a sputter deposition process to increase thermal stability and improve electrical conductivity of the copper layer.

2. Description of the Related Art

Copper and copper alloys have excellent electrical conductivity, thermal conductivity and physical properties at room temperature are useful in the fabrication of devices with dissimilar elements.

In addition to excellent electrical conductivity, copper also has excellent structural stability to prevent charged ions from migrating so an element such as a semiconductor element including a copper wire has long endurance and high stability. Thus, copper replaces aluminum (Al) and is deposited on a semiconductor element such as a silicon substrate (i.e. a silicon wafer) to form a copper film that is electrically conductive. Consequently, copper is useful in the semiconductor industry. However, the copper film still has some shortcomings inherent in methods used to form the copper film and in the chemical properties of copper.

Three examples exemplify the shortcomings. First, copper will oxidize.

Second, the copper film has a weak bond with a semiconductor element. Third, the copper film will react with silicon.

Conventional techniques of solving the third shortcoming include mounting a barrier that is insoluble with copper between the copper film and silicon substrate. However, semiconductor elements are becoming very small even nano-scale, so electrical resistivity of the copper film will increase, and manufacturing the copper film will be difficult when the barrier is less than 10 nm thick.

To obviate the foregoing problems, insoluble substances that are insoluble with copper are combined in the copper film to form a copper seed layer. Examples include those disclosed in the following documents: J. P. Chu, C. H. Chung, P. Y. Lee, J. M. Rigsbee, and J. Y. Wang, “Microstructure and Properties of Cu—C Pseudoalloy Films Prepared by Sputter Deposition” Metallurgical and Materials Transactions A, Vol. 29A, p. 647-658, (1998); J. P. Chu and T. N. Lin, “Deposition, Microstructure and Properties of Sputtered Copper Films Containing Insoluble Molybdenum” Journal of Applied Physics, 85, p. 6462-6469 (1999); C. H. Lin, J. P. Chu, T. Mahalingam, T. N. Lin and S. F. Wang, “Thermal Stability of Sputtered Copper Films Containing Dilute Insoluble Tungsten: A Thermal Annealing Study” Journal of Materials Research, Vol. 18, No. 6, p. 1429-1434 (2003); J. P. Chu and C. H. Lin, “Formation of a Reacted Layer at the Barrierless Cu(WN)/Si Interface” Applied Physics Letters, Vol. 87, p. 211902, (2005); J. M. E. Harper and F. M D'Heurle, “High Conductivity Copper-boron Alloys Obtained by Low Temperature Annealing” Journal of Electronic Materials, Vol. 30, p. LI, (2001); P. Kapur, J. P. McVittie, and K. C. Saraswat, “Technology and Reliability Constrained Future Copper Interconnects—Part I: Resistance Modeling,” IEEE Trans. Electron Device, Vol. 49, p. 590. (2002); and also in R.O.C. patent Nos. 152100 (public No. 476799) and 1237328, each of which is incorporated herein by reference.

A prior art document, J. P. Chu and C. H. Lin, “Formation of a Reacted Layer at the Barrierless Cu(WN)/Si Interface” Applied Physics Letters, Vol. 87, p. 211902, (2005), discloses that copper is not deposited on the copper seed layer to form a copper layer. Unlike the prior art document addressed above, the thin copper film is deposited on the copper seed layer and temperature to form a Cu—Si compound will be elevated to 600° C., so the Cu—Si compound is difficult to form, and the copper layer retains a low electrical resistivity. Thus, a specific characteristic of the present invention is that the copper seed layer is deposited on the substrate to replace the conventional barrier.

People of ordinary skill in the art know that a sputter deposition process is an “atom-by-atom growth” method to allow at least two insoluble substances or compounds to be synthesize to form a supersaturated solid solution. Thus, the sputter deposition process will not be limited within traditional thermodynamics such as solid solubility and phase equilibrium and will easily synthesize materials that have been extremely difficult or even impossible to synthesize in the past. The characteristics of the materials manufactured by this process are non-equilibrium, metal complex materials with nano-scale microstructures, good thermal stability and high mechanical strength property.

To overcome the shortcomings, the present invention provides a copper layer and a method for manufacturing said copper layer to mitigate or obviate the aforementioned shortcomings.

### SUMMARY OF THE INVENTION

The primary objectives of the present invention are to provide a copper layer and a method for manufacturing said copper layer, and more particularly to a copper layer that has a copper seed layer with insoluble substances to replace conventional barriers and is manufactured by a sputter deposition process to increase thermal stability and improve electrical conductivity of the copper layer.

To achieve the objective, the copper layer in accordance with the present invention is deposited on a substrate and comprises a copper seed layer and an interface. The copper seed layer contains insoluble substances that are insoluble with copper. The insoluble substances are selected from the group consisting of high-temperature metals (W, Mo, Nb, Ta, V, Cr), high-temperature metal nitrides (WN_{X}, MoN_{X}, NbN_{X}, TaN_{X}, VN_{X}, CrN_{X} or the like) and a mixture thereof. The interface is formed between the copper seed layer and the substrate. The copper seed layer replaces a conventional barrier to improve thermal stability of the copper layer to obtain some additional properties such as a fine microstructure, high thermal stability and excellent low electrical resistivity.

The method for manufacturing said copper layer in accordance with the present invention comprises steps of (a) sputtering copper with insoluble substances on a substrate to form a copper seed layer and (b) annealing the substrate and the copper layer to form an interface.

Other objectives, advantages and novel features of the invention will become more apparent from the following detailed description when taken in conjunction with the accompanying drawings.

### BRIEF DESCRIPTION OF THE DRAWINGS

FIG. 1 is a cross-sectional view of a copper seed layer in accordance with the present invention mounted on a substrate;

FIG. 2 is a flow chart of a method in accordance with the present invention to manufacture the copper seed layer as FIG. 1;

FIG. 3 is a graph of X-ray diffraction pattern (XRD) of Cu/Cu(W)/Si, Cu/Cu(Mo)/Si and Cu/Cu(WN)/Si at different annealing temperatures and pure copper annealed at 400° C.;

FIG. 4 is a Transmission Electron Microscopy (TEM) image of Cu/Cu(WN)/Si annealed for 1 hour at 600° C.;

FIG. 5 is a cross-sectional Focused Ion Beam (FIB) image of (a) Cu/Cu(W)/Si, (b) Cu/Cu(Mo)/Si, (c) Cu/Cu(WN)/Si annealed for 1 hour at 490° C., 500° C. and 600° C.; and

FIG. 6 is a graph of electrical resistivity of Cu/Si, Cu/Cu(W)/Si, Cu/Cu(Mo)/Si and Cu/Cu(WN)/Si relative to annealed temperature.

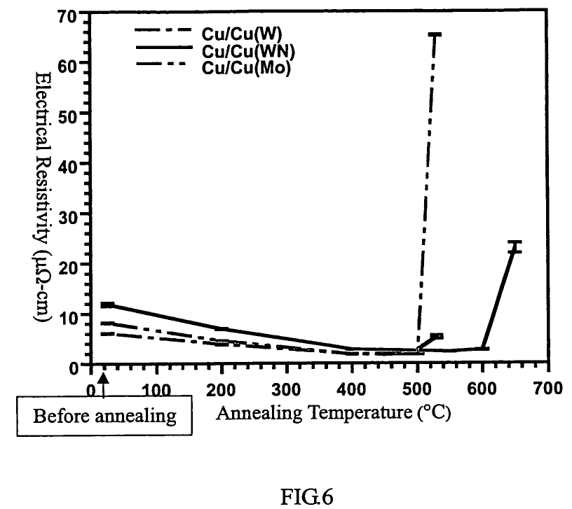

### DETAILED DESCRIPTION OF THE INVENTION

The present invention comprises a copper layer and a method for manufacturing said copper layer.

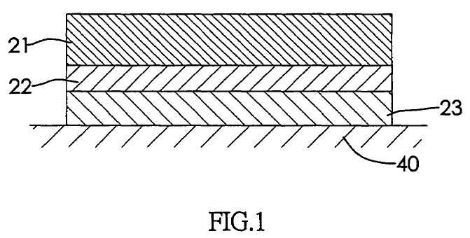

With reference to FIG. 1, the copper layer in accordance with the present invention is deposited on a substrate (40) that may be silicon such as a silicon wafer and comprises a copper seed layer (22), a thin copper film (21), and an interface (23).

The copper seed layer (22) has properties such as a fine microstructure, high thermal stability and excellent low electrical resistivity and contains copper and insoluble substances. The insoluble substances supersaturated with copper to form Cu(X), are selected from the group consisting of high-temperature metals (W, Mo, Nb, Ta, V, Cr), high-temperature metal nitrides (WN_{X}, MoN_{X}, NbN_{X}, TaN_{X}, VN_{X}, CrN_{X} or the like) and a mixture thereof and are in a range of 0.5 to 3.5 atom % The high temperature metal nitrides are less than 2.0 atom %. Tungsten of the insoluble substances may react with oxygen to form copper tungsten oxides.

The thin copper film (21) is deposited on a top of the copper seed layer (22), so the copper seed layer (22) with the thin copper film (21) further has high thermal stability, a low electrical resistivity and high conductivity and is suitable for use in many industries such as the semiconductor industry and in any copper manufacturing process without a conventional barrier.

The interface (23) is formed between the copper seed layer (22) and the substrate and may be silicon oxynitrides (SiOₓN_{y}) such as Si₂N₂O or Cu₂WO₄, Cu₃Si or the like. The interface (23) is thinner when the thin copper film (21) is deposited on the copper seed layer (22) than when the thin copper film (21) is not deposited on the copper seed layer (22). The interface (23) is formed between the substrate (40) and the copper seed layer (22) and performs the following functions:
(a) serves as a passivation layer to stop other gas from entering the substrate (40);
(b) is a diffusion barrier to stop reaction between copper and silicon in the substrate (40); and
(c) is a high dielectric layer especially when compared to silicon dioxide (SiO₂).

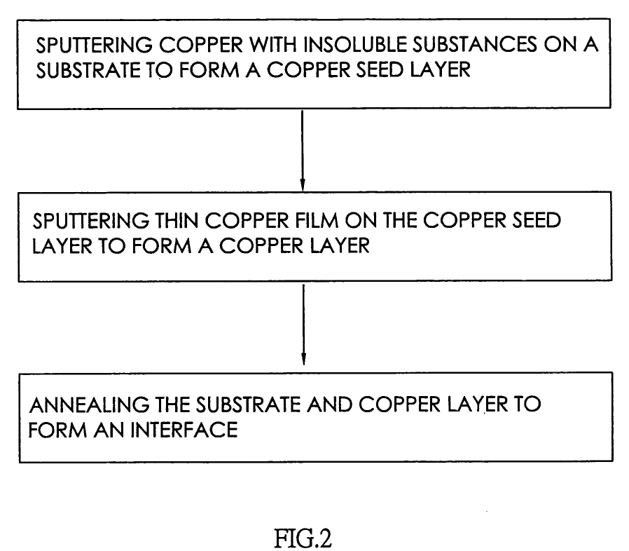

With reference to FIG. 2, a method for manufacturing said copper layer in accordance with the present invention is a sputter deposition procedure and comprises steps of (a) sputtering copper with insoluble substances on a substrate to form a copper seed layer, (b) sputtering a thin copper film on the copper seed layer to form a copper layer, (c) annealing the substrate and the copper layer to form an interface.

Step (a) comprises simultaneously sputtering copper with insoluble substances on a substrate in a vacuum in a sputtering chamber with an operational gas to form a copper seed layer. The sputtering is conducted at or near room temperature and 150 watts (W). The insoluble substances are in a range of 0.5 to 3.5 atom % and comprise high-temperature metals and high-temperature metal nitrides. The high temperature metals include W, Mo, Nb, Ta, V and Cr. The high temperature metal nitrides include WN_{X}, MoN_{X}, NbN_{X}, TaN_{X}, VN_{X}, or the like and are less than 2.0 atom %. The working pressure in the sputtering chamber is 1×10⁻² to 1×10⁻³ torr. The temperature in the sputtering chamber may be from room temperature to 200° C. The operational gas is argon or a mixture of argon and a trace-amount of nitrogen.

Step (b) comprises sputtering a thin copper film on the copper seed layer to form a copper layer. The sputtering is conducted in a vacuum (7×10⁻³ torr) at 70° C. with an operational gas. The operational gas is argon (Ar).

Step (c) comprises annealing the substrate and the copper layer at a high temperature in a vacuum to form the interface between the substrate and the copper seed layer by heating the substrate and the copper layer at a slow rate, holding the copper layer at a high annealing temperature for 1 hour and cooling the copper layer at a slow rate. The slow rates for heating and cooling are in a range of 4° C./min to 6° C./min. The vacuum during annealing is in a range of 1×10⁻⁶ to 1×10⁻⁷ torr. Annealing the copper layer on the substrate causes the interface to spontaneously form between the substrate and the copper seed layer.

After the step (c), the copper layer has an electrical resistivity close to that of pure Cu deposited on the silicon substrate.

The method as described has a number of advantages. Because the interface is produced automatically when the copper layer and the substrate is annealed, chemical vapor deposition (CVD) normally conducted at a high temperature is not required. In the method, the interface will be formed during annealing simultaneously, which significantly reduces procedural complexity and cost of the formation of the copper layer.

The following examples with the accompanying drawings are provided to assist a person with ordinary skill in the art to understand and to practice the invention. These examples are only exemplary or illustrative of the application of the principles of the present invention.

1. A method for manufacturing a copper seed layer with insoluble substances (Cu/Cu(X) wherein x is insoluble substances):

Direct current (DC) magnetron sputter deposition in a vacuum sputtering system having a sputtering chamber to co-sputter copper and insoluble substances on the substrate to form a copper seed layer.
(a) Conditions: Pressure the sputtering chamber of the vacuum sputtering system was lower than 7×10⁻⁷ torr. High purity argon or a mixture of high purity argon and a trace-amount of N₂ were injected into the sputtering chamber. 150 watt (W) was used in the following processes. The sputtering materials were copper and the insoluble substances, and the substrate was a silicon wafer without a barrier.
(b) Process: The silicon wafer was sputtered simultaneously copper with the insoluble substances to form the copper seed layer. When sputtering, the silicon wafer was rotated at a specific rate to obtain a uniform and thin copper seed layer. Other important parameters for the procedure are shown in Table 1.

TABLE 1

| Parameters | Value |
|---|---|
| System Basic Vacuum Pressure | Below 7 × 10⁻⁷ torr |
| Argon/Nitrogen Working Pressure | 1 × 10⁻² torr |
| DC Sputter Power | 150 W |
| Substrate Temperature | Normal temperature (without |
| | heating) to 200° C. |
| Relative Position and Distance of the | The substrate is located 20 cm |
| Sputtering Material and the Substrate | above the sputtering Material |
| Sputtering Rate | 4.8 nm/min |

(c) Additional process: More thin copper film can be deposited on the copper seed layer wafer in the vacuum sputtering system.

2. Quality analysis, quantity analysis and thermal stability of the insoluble substances in the copper seed layer:

The quantity of the insoluble substances in the copper seed layer was measured by electron probe for microanalysis (EMPA) as shown in Table 2.

TABLE 2
The atom percentage of the insoluble substances
contained in Cu seed layer

| Tungsten (at %) | Nitrogen (at %) | Molybdenum (at %) |
|---|---|---|
| 0.5–3.5 | 0–2.0 | 1.5–3.5 |

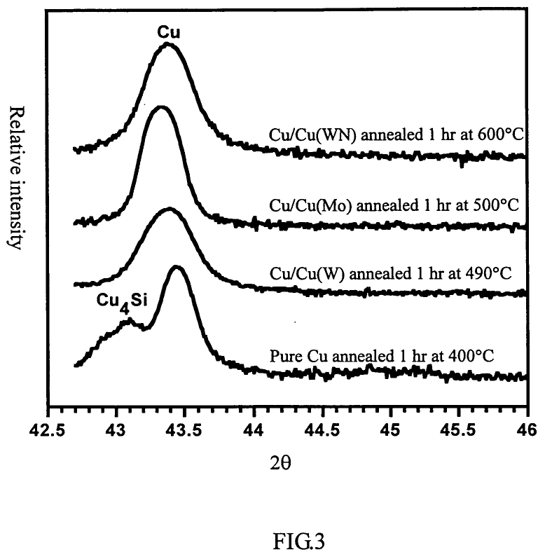

With reference to FIG. 3, an X-ray diffraction (XRD) diagram after pure copper, Cu/Cu(W), Cu/Cu(Mo) and Cu/Cu(WN) were annealed. Compared to pure copper and a copper seed layer without a thin copper film, temperatures of pure Cu, Cu/Cu(W), Cu/Cu(Mo) and Cu/Cu(WN) to form Cu—Si compounds respectively raise to 490° C., 500° C. and 600° C. After Cu/Cu(WN) was annealed 1 hour at 600° C., an interface between Cu(WN) and the silicon substrate has a thickness of 0˜75 nm.

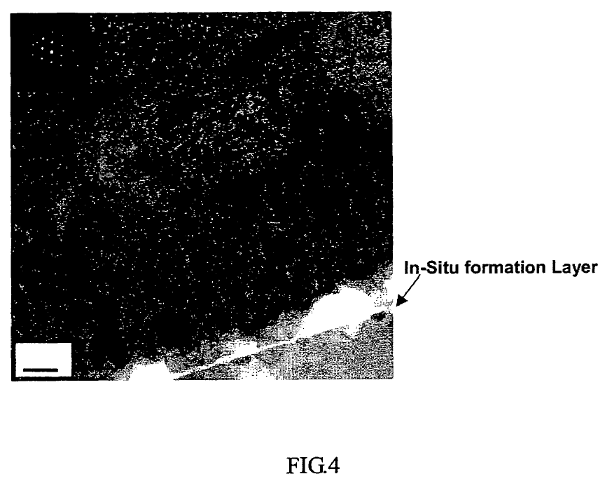

With reference to FIG. 4, an interface between the copper seed layer and the silicon substrate was observed and analyzed by transmission electron microscopy (TEM) and diffraction pattern analyses. The interfaces comprise Cu₂WO₄, Si₂N₂O and Cu₃Si. When the copper seed layer has a thin copper film, the thin copper film stops oxygen from entering the copper seed layer and prevents the interface from getting thicker.

Consequently, the temperature to form Cu—Si is elevated, and the interface is thin when the copper seed layer is deposited with a thin copper film.

3. Property measurement of the copper seed layer with the high-temperature metal nitrides:

The microstructure of the thin copper film and the copper seed layer containing insoluble substances are described below.

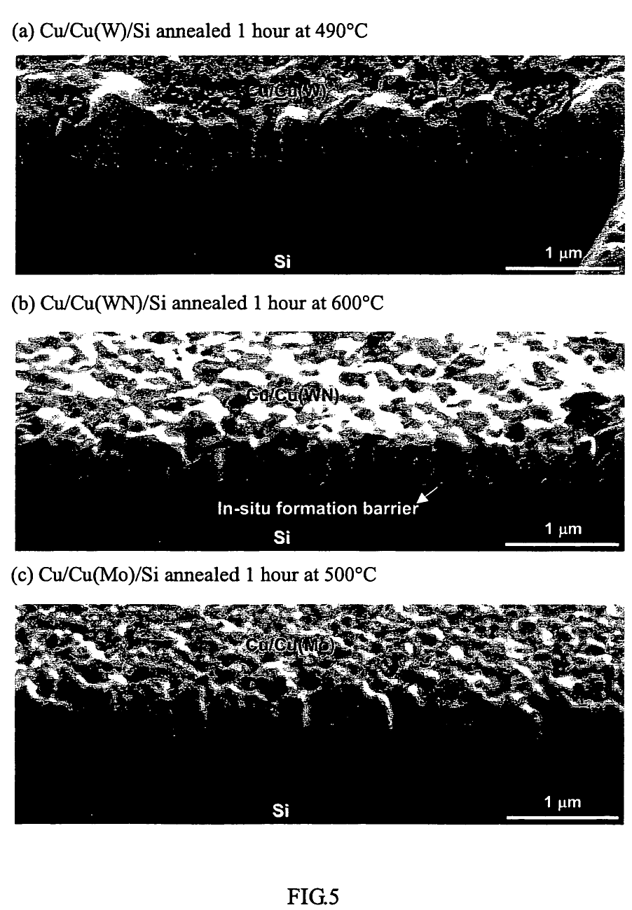

With reference to FIG. 5, a cross-sectional view of focus ion beam (FIB) image show that the thin copper film deposited on Cu/Cu(W) and Cu/Cu(Mo) recrystallized and the copper seed layer still retained a columnar structure after being annealed respectively at 490° C. and 500° C. The FIB results are the same as the results in XRD.

A non-uniform interface between the copper seed layer and the silicon substrate occurred after Cu/Cu(WN) was annealed 1 hour at 600° C. According to the TEM graph in FIG. 4, the interface was 0˜75 nm thick. In addition, the interface stopped forming the Cu—Si compound.

Compared to prior art, J. P. Chu and C. H. Lin, “Formation of a reacted layer at the Barrier-Free Cu(WN)/Si interface, “Applied Physics Letters, Vol. 87, p. 212902, (2005), not having the thin copper film deposited on the copper seed layer, the temperature forming the Cu—Si compound is elevated to 600° C. while electrical resistivity is still low when the copper seed layer is deposited with thin copper film.

With reference to FIG. 4, the electrical resistivity of Cu/Cu(W), Cu/Cu(Mo), Cu/Cu(WN) and pure copper were measured before and after they were annealed. The results show that the electrical resistivity is higher before Cu/Cu(W), Cu/Cu(Mo), Cu/Cu(WN) and copper were annealed than after they were annealed. Because thin copper film layer deposited on the copper seed layer recrystallized after being annealed, electrical resistivity of Cu/Cu(W), Cu/Cu(Mo) and Cu/Cu(WN) were reduced respectively to 1.8 μΩ-cm, 1.7 μΩ-cm and 2.7 μΩ-cm and are lower than the electrical resistivity of the copper seed layer without the thin copper film.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A copper layer being deposited on a substrate, the copper layer comprising
a copper seed layer containing copper and insoluble substances that are insoluble with copper; and
an interface being formed between the copper seed layer and the substrate.

2. The copper layer as claimed in claim 1, wherein the substrate is silicon and the interface comprises Cu₂WO₄, Si₂N₂O and Cu₃Si.

3. The copper layer as claimed in claim 1, wherein the interface has a thickness at 0˜75 nm.

4. The copper layer as claimed in claim 1, wherein the insoluble substances are selected from the group consisting of high-temperature metals, high-temperature metal nitrides and a mixture thereof.

5. The copper layer as claimed in claim 4, wherein the insoluble substances in the copper seed layer are in a range of 0.5-3.5 atom %.

6. The copper layer as claimed in claim 4, wherein the high-temperature metal nitrides are less than 2.0 atom %.

7. The copper layer as claimed in claim 1 further comprising a thin copper film deposited on a top of the copper seed layer.

8. A method for manufacturing a copper layer, which is a sputter deposition process, comprising:
(a) simultaneously sputtering copper with insoluble substances that are insoluble with copper on a substrate in a vacuum of 1×10⁻² to 1×10⁻³ torr in a sputtering chamber with an operational gas at or near room temperature to form a copper seed layer;
(b) sputtering a thin copper film on the copper seed layer in a vacuum of 7×10⁻³ torr at or near room temperature to form a copper layer; and
(c) annealing the copper layer and the substrate at a high temperature in a vacuum to form an interface between the substrate and the copper seed layer.

9. The method as claimed in claim 8, wherein the temperature in the sputtering chamber is from room temperature to 200° C.

10. The method as claimed in claim 8, wherein the operational gas in the (a) step is a mixture of argon and a trace-amount of nitrogen.

11. The method as claimed in claim 8, wherein after the (c) step, the copper layer has an electrical resistivity close to that of pure Cu deposited on the silicon substrate.

12. The method as claimed in claim 8, wherein the substrate is silicon and the interface comprises Cu₂WO₄, Si₂N₂O and Cu₃Si.

13. The method as claimed in claim 8, wherein the interface has a thickness at 0˜75 nm.

14. The method as claimed in claim 8, wherein the insoluble substances are
high-temperature metals; and
high-temperature metal nitrides.

15. The method as claimed in claim 8, wherein the insoluble substances in the copper seed layer are in a range of 0.5-3.5 atom %.

16. The method as claimed in claim 8, wherein the high-temperature metal nitrides are less than 2.0 atom %.
